(19) United States
(12) Patent Application Publication
(10) Pub. No.: US 2026/0309770 A1
(43) Pub. Date: Oct. 8, 2026

(54) BURN-IN BOARD, BURN-IN APPARATUS, AND BURN-IN PROCESS

(71) Applicant: NANYA TECHNOLOGY CORPORATION, NEW TAIPEI CITY (TW)

(72) Inventors: PO-HUNG CHEN, NEW TAIPEI CITY (TW); LI-ZUO SYU, NEW TAIPEI CITY (TW); JEN-PANG WANG, NEW TAIPEI CITY (TW)

(21) Appl. No.: 19/098,121

(22) Filed: Apr. 2, 2025

(51) Int. Cl. G01R 31/28

(52) U.S. Cl. CPC G01R 31/2863; G01R 31/2862

(57) ABSTRACT

The present application discloses a burn-in board, a burn-in apparatus, and a burn-in process. The burn-in board includes a board-substrate including a front surface and a back surface; a plurality of sockets mounted on the front surface of the board-substrate; and a wiring system positioned in the board-substrate and electrically connected to the sockets. The plurality of sockets are configured into groups by the wiring system. The groups respectively include four sockets arranged in a 2×2 square matrix.

### TECHNICAL FIELD

The present disclosure relates to a burn-in board, a burn-in apparatus with the burn-in board, and a burn-in process with the burn-in board, and more particularly, to a burn-in board with grouped sockets.

### DISCUSSION OF THE BACKGROUND

Semiconductor devices are used in a variety of electronic applications, such as personal computers, cellular telephones, digital cameras, and other electronic equipment. The dimensions of semiconductor devices are continuously being scaled down to meet the increasing demand of computing ability. However, a variety of issues arise during the scaling-down process, and such issues are continuously increasing. Therefore, challenges remain in achieving improved quality, yield, performance, and reliability and reduced complexity.

This Discussion of the Background section is provided for background information only. The statements in this Discussion of the Background are not an admission that the subject matter disclosed in this section constitutes prior art to the present disclosure, and no part of this Discussion of the Background section may be used as an admission that any part of this application, including this Discussion of the Background section, constitutes prior art to the present disclosure.

### SUMMARY

One aspect of the present disclosure provides a burn-in board including a board-substrate including a front surface and a back surface; a plurality of sockets mounted on the front surface of the board-substrate; and a wiring system positioned in the board-substrate and electrically connected to the sockets. The plurality of sockets are configured into groups by the wiring system. The groups respectively include four sockets arranged in a 2×2 square matrix.

Another aspect of the present disclosure provides a burn-in apparatus including a burn-in chamber; a burn-in board accommodated in the burn-in chamber; a test power supply electrically connected to the burn-in board; and a burn-in controller electrically connected to the burn-in board. The burn-in board includes a board-substrate including a front surface and a back surface, a plurality of sockets mounted on the front surface of the board-substrate, and a wiring system positioned in the board-substrate and electrically connected to the sockets, wherein the plurality of sockets are configured into groups by the wiring system, and the groups respectively includes four sockets arranged in a 2×2 square matrix.

Another aspect of the present disclosure provides a burn-in process including providing a plurality of devices under test; providing a burn-in board including a board-substrate including a front surface and a back surface, a plurality of sockets mounted on the front surface of the board-substrate, and a wiring system positioned in the board-substrate, electrically connected to the sockets, and configured the plurality of sockets into groups, wherein the groups respectively includes four sockets arranged in a 2×2 square matrix; installing the plurality of devices under test on the plurality of sockets; placing the burn-in board into a burn-in chamber of a burn-in apparatus and electrically connecting the burn-in board and the burn-in apparatus; performing a stress test to the plurality of devices under test; providing to and receiving from signals from the plurality of devices under test by a burn-in controller of the burn-in apparatus through the wiring system of the burn-in board; and recording test results by the burn-in controller of the burn-in apparatus.

Due to the design of the burn-in board of the present disclosure, the number of sockets can be increased (e.g., up to a total of 320 sockets) without compromising signal synchronization either among sockets in different groups or within the same group. This is achieved through the tailored design of the signal transmission path according to the wiring system.

The foregoing has outlined rather broadly the features and technical advantages of the present disclosure in order that the detailed description of the disclosure that follows may be better understood. Additional features and advantages of the disclosure will be described hereinafter and form the subject of the claims of the disclosure. It should be appreciated by those skilled in the art that the conception and specific embodiment disclosed may be readily utilized as a basis for modifying or designing other structures or processes for carrying out the same purposes of the present disclosure. It should also be realized by those skilled in the art that such equivalent constructions do not depart from the spirit and scope of the disclosure as set forth in the claims appended.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIG. 1 is a front view illustrating a burn-in apparatus in accordance with one embodiment of the present disclosure;

FIG. 2 is a block diagram illustrating a system configuration of the burn-in apparatus in accordance with one embodiment of the present disclosure;

FIGS. 3 and 4 are schematic plan views showing a wiring system of the burn-in board in accordance with one embodiment of the present disclosure;

FIG. 5 illustrates a wiring circuit of the burn-in board in accordance with one embodiment of the present disclosure;

FIG. 6 illustrates a signal characteristic in the wiring circuit of FIG. 5;

FIG. 7 is a graph illustrating the rise time of signals transmitting through the wiring circuit of FIG. 5;

FIG. 8 illustrates a wiring circuit of the burn-in board in accordance with another embodiment of the present disclosure;

FIG. 9 is a perspective view of the burn-in board with a flexure prevention structure in accordance with one embodiment of the present disclosure;

FIG. 10 is a vertical sectional view of the burn-in board with the flexure prevention structure in accordance with one embodiment of the present disclosure;

FIG. 11 is a perspective view of the burn-in board with a flexure prevention structure in accordance with another embodiment of the present disclosure;

FIG. 12 is a perspective view showing a portion of the flexure prevention structure provided on the burn-in board in accordance with another embodiment of the present disclosure;

FIG. 13 is a vertical sectional view of the burn-in board with the flexure prevention structure in accordance with another embodiment of the present disclosure;

FIGS. 14 and 15 illustrate wiring circuits of a burn-in board in accordance with one embodiment of the present disclosure;

FIGS. 16 and 17 are graphs illustrating the rise time of signals transmitting through the wiring circuits in FIGS. 14 and 15; and

FIG. 18 illustrates, in a flowchart diagram form, a burn-in process in accordance with one embodiment of the present disclosure.

### DETAILED DESCRIPTION

The following disclosure provides many different embodiments, or examples, for implementing different features of the subject matter provided. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be oriented (rotated 90 degrees or at other orientations) and the spatially relative descriptors used herein may likewise be interpreted accordingly.

It should be understood that when an element or layer is referred to as being “connected to” or “coupled to” another element or layer, it can be directly connected to or coupled to another element or layer, or intervening elements or layers may be present.

It should be understood that, although the terms first, second, etc. may be used herein to describe various elements, these elements should not be limited by these terms. Unless indicated otherwise, these terms are only used to distinguish one element from another element. Thus, for example, a first element, a first component or a first section discussed below could be termed a second element, a second component or a second section without departing from the teachings of the present disclosure.

Unless the context indicates otherwise, terms such as “same,” “equal,” “planar,” or “coplanar,” as used herein when referring to orientation, layout, location, shapes, sizes, amounts, or other measures do not necessarily mean an exactly identical orientation, layout, location, shape, size, amount, or other measure, but are intended to encompass nearly identical orientation, layout, location, shapes, sizes, amounts, or other measures within acceptable variations that may occur, for example, due to manufacturing processes. The term “substantially” may be used herein to reflect this meaning. For example, items described as “substantially the same,” “substantially equal,” or “substantially planar,” may be exactly the same, equal, or planar, or may be the same, equal, or planar within acceptable variations that may occur, for example, due to manufacturing processes.

It should be noted that, in the description of the present disclosure, above (or up) corresponds to the direction of the arrow of the Z direction, and below (or down) corresponds to the opposite direction of the arrow of the Z direction.

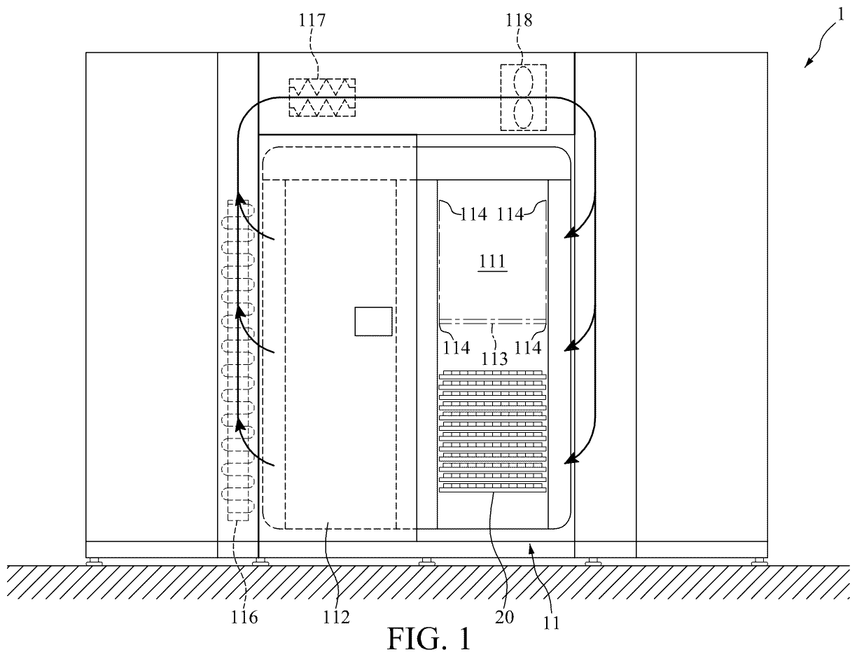

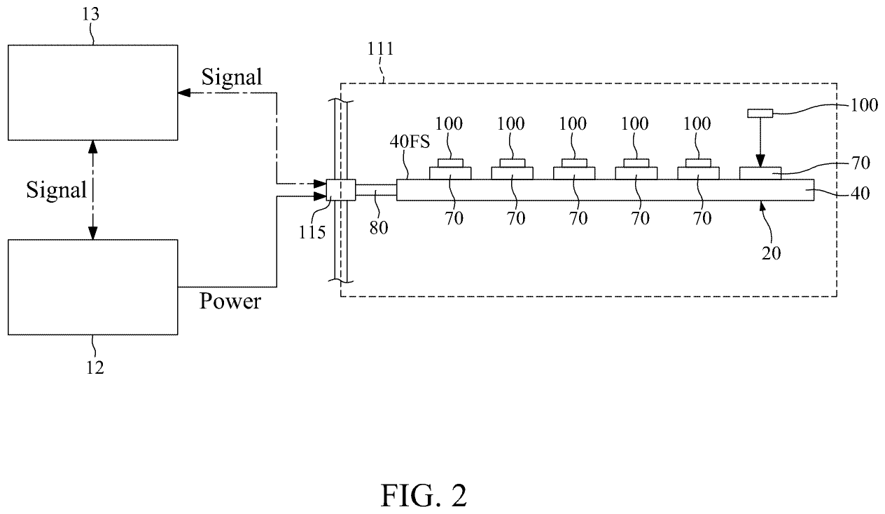

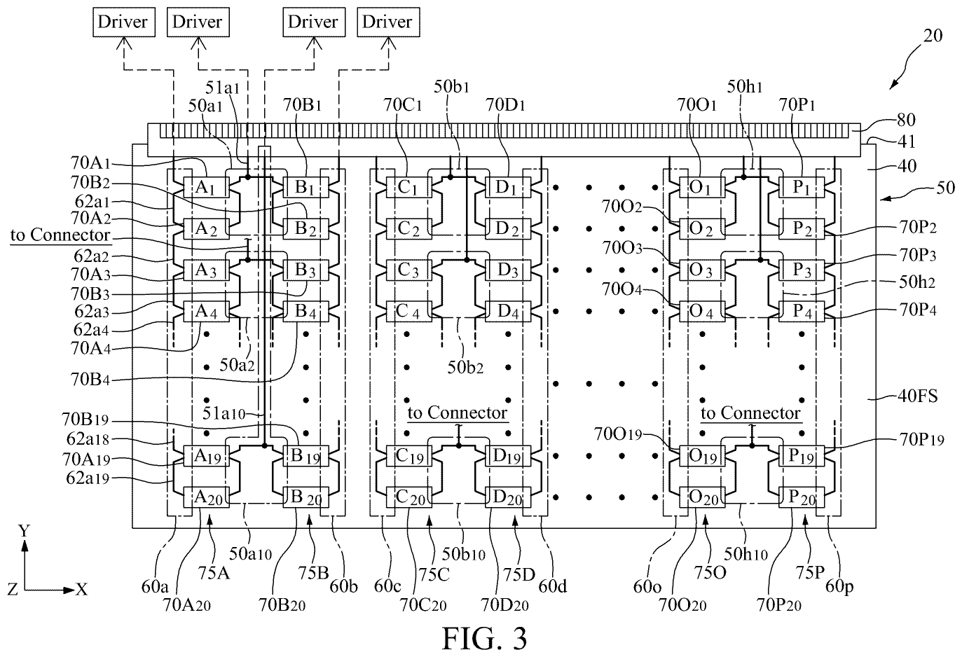

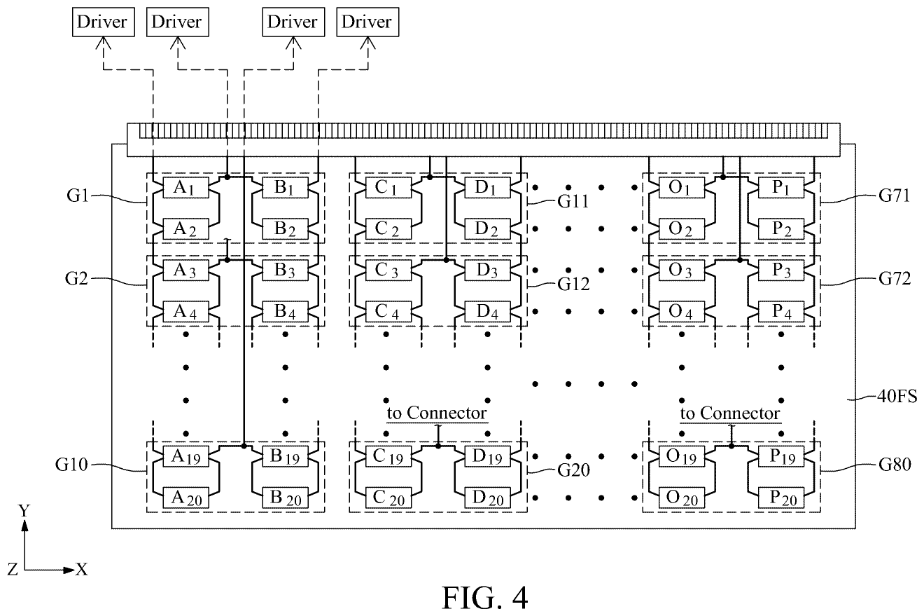

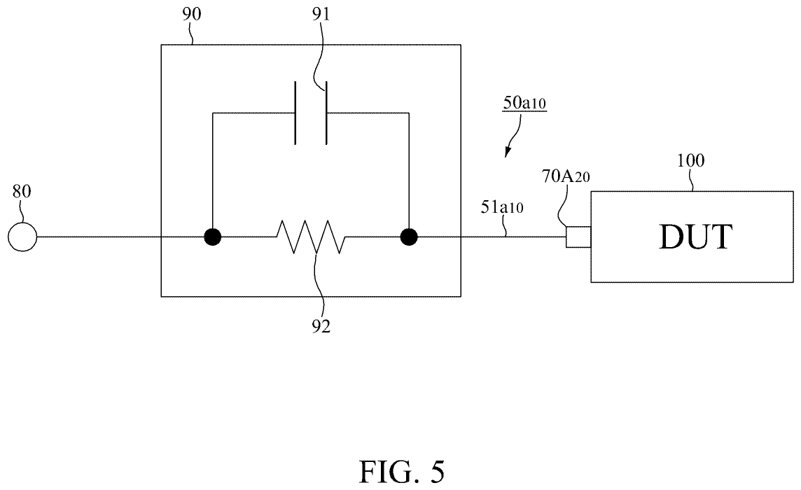

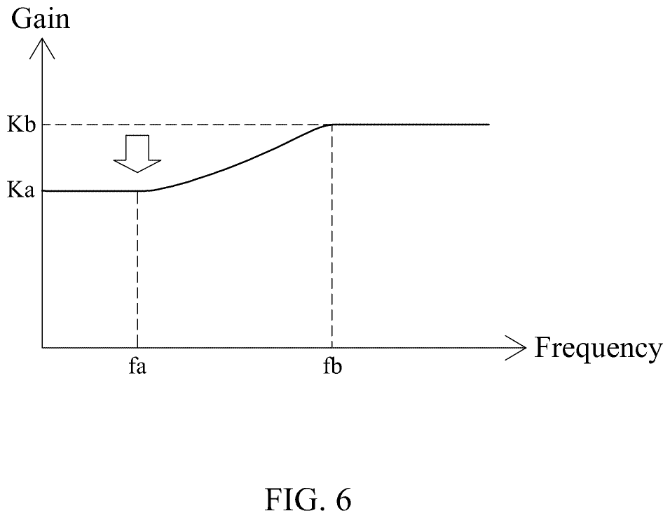

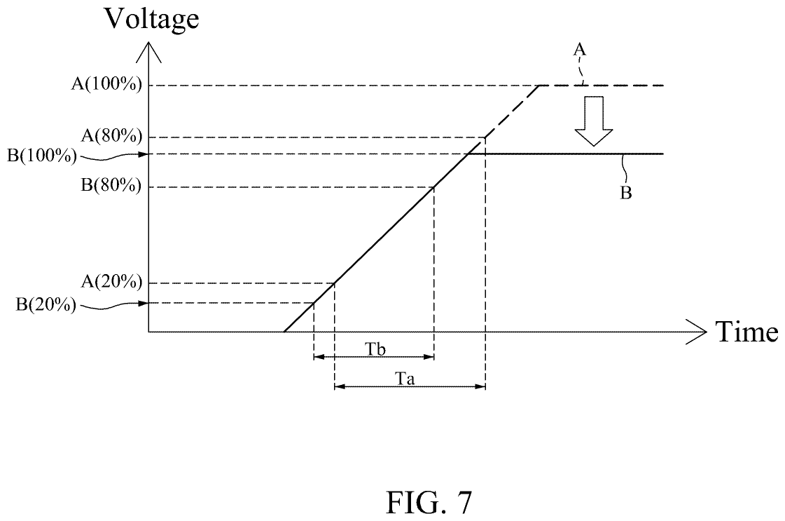

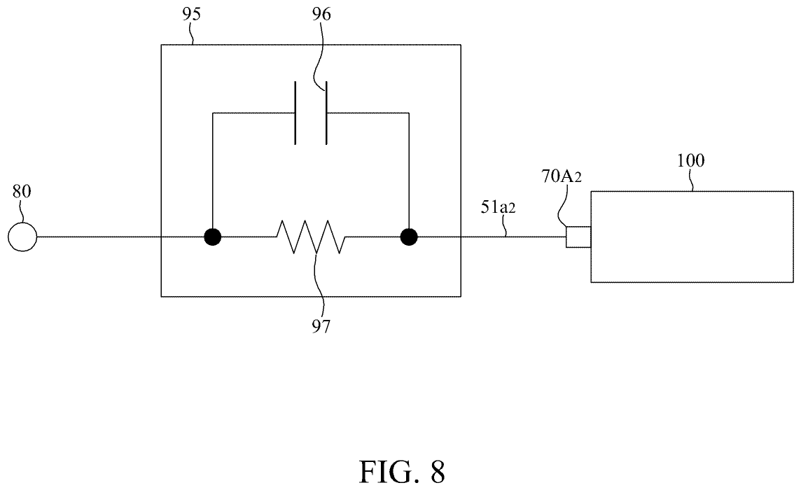

FIG. 1 is a front view illustrating a burn-in apparatus 1 in accordance with one embodiment of the present disclosure. FIG. 2 is a block diagram illustrating a system configuration of the burn-in apparatus 1 in accordance with one embodiment of the present disclosure. FIGS. 3 and 4 are schematic plan views showing a wiring system 50 of the burn-in board 20 in accordance with one embodiment of the present disclosure. FIG. 5 illustrates a wiring circuit of the burn-in board 20 in accordance with one embodiment of the present disclosure. FIG. 6 illustrates a signal characteristic in the wiring circuit of FIG. 5. FIG. 7 is a graph illustrating the rise time of signals transmitting through the wiring circuit of FIG. 5. FIG. 8 illustrates a wiring circuit of the burn-in board 20 in accordance with another embodiment of the present disclosure.

A burn-in process is used in testing hardware components to identify defective devices through stress testing. During this process, components may be subjected to conditions involving higher or more sustained voltages than those typically experienced during regular operation. To further amplify the stress, the burn-in process may be conducted in an environment with elevated temperatures, such as a burn-in apparatus.

The components undergoing the burn-in process may be connected to the burn-in apparatus, which typically consists of a burn-in chamber and a burn-in controller. The burn-in chamber may accommodate a burn-in board. The burn-in board may include sockets that allows multiple devices under test (DUTs, i.e., the hardware components) to be mounted and simultaneously subjected to the burn-in process. The burn-in apparatus, integrated with the burn-in chamber, may be responsible for providing and receiving various signals to and from the DUTs through the burn-in board.

In operation, the burn-in apparatus may apply a power supply voltage to the DUTs and facilitate the input and output of signals while simultaneously subjecting the DUTs to thermal stress. For example, the thermal stress may range from about −25° C. to about +125° C. By combining electrical and thermal stress in a controlled environment, the burn-in process enables effective screening of DUTs for reliability and defect identification.

With reference to FIGS. 1 and 2, a burn-in apparatus 1 may be provided. In some embodiments, the burn-in apparatus 1 may include a burn-in chamber 11, a test power supply 12, and a burn-in controller 13. The burn-in chamber 11 may accommodate a plurality of burn-in boards 20 and apply thermal stress to devices under test 100 (DUTs 100) mounted on the burn-in boards 20 during a burn-in process.

In some embodiments, the burn-in chamber 11 may include a thermostatic room 111 defined by a heat-insulating wall and equipped with a door 112 that can open and close to allow access. Inside the thermostatic room 111, a plurality of slots 113 may be arranged, each equipped with a pair of rails 114 supporting both ends of the burn-in boards 20. The burn-in boards 20 may slide into position along the rails 114 through the door 112. In some embodiments, the thermostatic room 111 may contain two rows of slots 113, with 24 stages per row, accommodating up to 48 burn-in boards 20. The specific number and arrangement of the slots 113 can be adjusted based on testing efficiency and other considerations. Each slot 113 may include a connector electrically connected to the test power supply 12 and the burn-in controller 13, ensuring all burn-in boards 20 are properly integrated into the burn-in apparatus 1.

In some embodiments, the burn-in chamber 11 may be also equipped with an evaporator 116, a heater 117, and a fan 118 to regulate the temperature inside the thermostatic room 111. The air within the thermostatic room 111 may be either cooled by the evaporator 116 or heated by the heater 117, while the fan 118 ensure even circulation. These components work in coordination, under the control of the burn-in controller 13, to maintain the desired thermal stress conditions. The test power supply 12 and the burn-in controller 13 may be connected to each DUT 100 on the burn-in boards 20 via the connectors 115 of burn-in apparatus 1, supplying the necessary voltage and controlled signals.

The burn-in controller 13 may play a vital role in the burn-in process. It may manage the voltage application to the DUTs 100, control the input and output of signals, and regulate the temperature adjustments within the thermostatic room 111. Additionally, the burn-in controller 13 may monitor the DUTs 100 during the burn-in process, identifying devices with abnormal responses as defective. It records the serial numbers of such defective DUTs, corresponding to their slot and position on the burn-in boards 20, and compile test results for feedback. This integrated approach ensures thorough screening and reliable identification of defective devices. In some embodiments, the burn-in controller 13 may supply signals to the burn-in boards 20 over multiple channel types, including clock channels (CLK), scan channels (SCAN), input/output channels (I/O), and optionally address channels (ADD) but is not limited thereto.

In some embodiments, the DUT 100 may include a memory component (e.g., static random access memory (SRAM), synchronous dynamic random access memory (SDRAM), flash memory (e.g., high capacity NOR/NAND flash memory), memory cards (e.g., high capacity Secure Digital (SD), Micro SD, Compact Flash, Solid State Disk (SSD), or any other non-volatile memory, memory card, memory module, or other semiconductor device).

With reference to FIGS. 2 and 3, the burn-in boards 20 may be key components for the burn-in process and may respectively include a board-substrate 40, a plurality of sockets 70 for accommodating DUTs 100, a wiring system 50, and a connector 80 for establishing an electrical connection with the connector 115 of burn-in apparatus 1. Each element may play a specific role in ensuring the functionality and reliability of the burn-in process.

For brevity, clarity, and convenience of description, only one burn-in board 20 is described.

In some embodiments, the board-substrate 40 may serve as the foundation of the burn-in board, providing a platform on which the other components are mounted. In some embodiments, the board-substrate 40 may have approximately a rectangular shape. In some embodiments, the board-substrate 40 may be formed of a material having insulating property. In some embodiments, the board-substrate 40 may be formed of, for example, flame retardant 4 materials, composite epoxy materials, polyimide, or other applicable insulating materials. In some embodiments, the board-substrate 40 may be a multilayer board, and the wiring systems 50 may be constituted by a conductive path such as a wiring pattern and a via hole formed in the board-substrate 40.

The connector 80 may be positioned at one end of the board-substrate 40, allowing the connector 80 of the burn-in board 20 to interface with the burn-in chamber 11. The alignment between the connector 80 of the burn-in board 20 and the connector 115 of burn-in apparatus 1 establishes an electrical connection between the sockets 70 and the burn-in controller 13. The wiring length from each socket 70 to the connector depends on the socket's position on the burn-in board 20.

In some embodiments, the sockets 70 may be arranged in a matrix pattern on the front surface 40FS of the board-substrate 40. For example, twenty sockets 70 are aligned in each row along one direction, forming socket rows labeled sequentially (e.g., Row 75A, Row 75B). The burn-in board 20 may include sixteen rows (e.g., Row 75A to Row 75P), with twenty sockets per row, resulting in a total of 320 sockets. This arrangement maximizes the board's capacity and efficiency. However, the number of sockets and their arrangement can be adjusted as needed to meet specific testing requirements.

In some embodiments, each socket 70 may include multiple contact pins (e.g., 16 pins) that make electrical contact with the terminals of the DUTs 100. When a DUTs 100 is mounted, the contact pins ensure a secure and reliable electrical connection, enabling accurate testing.

The relationship between wiring length and signal delay is a critical factor in the design and performance of electrical systems, particularly in high-speed or high-frequency circuits. Signal delay, or propagation delay, refers to the time required for an electrical signal to travel from one point to another. This delay is directly influenced by the physical length of the wiring, as the signal must traverse the entire conductor at a finite propagation speed.

Longer wiring length increases the total resistance, capacitance, and inductance of the circuit. These parasitic elements collectively affect the signal's rise and fall times, slowing propagation and introducing delay. Wiring with branch points or splits, such as daisy-chained connections, exacerbates the issue by increasing the effective path length. Unequal wiring lengths from branch points can cause timing mismatches or skew, disrupting the synchronous operation of a circuit. The effects are particularly pronounced in high-frequency systems, where even minor differences in wiring length can lead to significant phase shifts due to shorter signal wavelengths, potentially causing constructive or destructive interference.

The material properties of the wiring and insulation, including conductivity and dielectric constant, also influence signal delay. These properties can vary with temperature, making longer wiring more susceptible to temperature-induced delays. In sensitive applications such as PCBs or burn-in boards, precise control of wiring lengths is essential to minimize skewing and ensure consistent signal arrival across all paths. Matching wiring lengths and managing branch points within strict tolerances are critical to maintaining data integrity and synchronization.

In some embodiments, the burn-in board 20 may include two types of wiring systems 50 such as first wiring systems 50a1 to 50h10 and second wiring systems 60a to 60p. The first wiring systems 50a1 to 50h10 and second wiring systems 60a to 60p may have distinct connection forms between the connector 80 and the sockets 70 on the board-substrate 40. The connection form, which represents the electrical connection topology between the connector 80 and the sockets 70, may be determined by the positional relationship of the wiring and branch points. The type of connection form is classified based on the presence or absence of branch points and their positions. The first wiring systems 50a1 to 50h10 feature a connection form with branch points, while the second wiring systems 60a to 60p adopt a connection form without branch points. The wiring system 50 is not limited to these two types and may include additional connection forms if needed.

The first wiring systems 50a1 to 50h10, represented by the example of 50a1, feature a branched connection topology. Between the connector 80 and the sockets 70, wiring branches to connect multiple sockets. For example, in the first wiring system 50a1, wiring branches into two paths between the connector 80 and sockets 70A₁ and 70B₁. Subsequently, sockets 70 aligned along the same direction, such as sockets 70A₁ and 70A₂ or 70B₁ and 70B₂, are connected in a daisy chain configuration. This topology ensures that the wiring lengths between branch points and their corresponding sockets, as well as between adjacent sockets within each daisy chain, are substantially equal. As a result, the signal transmission times for sockets connected through the same wiring system are effectively synchronized.

Similarly, subsequent first wiring systems, such as 50a2, 50a3, and so on, share the same configuration as 50a1. For example, the first wiring system 50a2 connects the connector to sockets 70A₃, 70A₄, 70B₃, and 70B₄, while the first wiring system 50a3 connects sockets 70A₅, 70A₆, 70B₅, and 70B₆. This pattern continues for all first wiring systems 50a1 to 50h10, with each system connecting four sockets arranged in two rows. The board-substrate 40 may incorporate a total of 80 first wiring systems to accommodate 320 sockets distributed across 16 socket rows.

In contrast, the second wiring system, exemplified by 60a, adopts a daisy chain connection topology without branch points. In this configuration, sockets within a single row, such as 70A₁ to 70A₂₀, are sequentially connected along a straight path. For example, in the second wiring system 60a, the sockets forming the socket row 75A are connected sequentially by connection lines 62a1 to 62a19. This configuration ensures simplicity in the wiring path and reduces complexity.

All subsequent second wiring systems, including 60b to 60p, follow the same structure as 60a, each connecting sockets in a single row. For example, the second wiring system 60b connects sockets 70B₁ to 70B₂₀, forming socket row 75B, while the second wiring system 60c connects sockets 70C₁ to 70C₂₀ in socket row 75C. In total, there are 16 second wiring systems on the board-substrate 40, each corresponding to one of the 16 socket rows.

The physical layout of the burn-in board 20 positions the connector 80 on one end, while the sockets 70 are aligned in rows along the board's length. Consequently, the wiring length between the connector 80 and the sockets 70 increases with the distance of the sockets 70 from the connector 80. For example, in the first wiring system 50a10, the wiring length to socket 70A₂₀ (farthest from the connector) is longer than that to socket 70A₁ (closest to the connector). This variation in wiring length is inherent to the layout and is managed by the consistent design of the connection forms to ensure stable signal transmission.

In the description of the present disclosure, the direction from the connector 80 to each of the socket rows 75A to 75P (i.e., the Y direction) may be referred to as the direction of signal transmission or the first direction.

With reference to FIGS. 2 to 4, in some embodiments, the sockets 70 may be grouped according to signal transmission path (e.g., the wiring system 50). In total, the sockets 70 are organized into 80 groups, labeled G1 through G80. Each group consists of four sockets 70, each capable of accommodating one DUT 100. Within a group, two sockets (e.g., 70A₁ and 70A₂) are aligned along the direction of signal transmission (i.e., the Y direction), while the other two sockets (e.g., 70B₁ and 70B₂) are positioned directly adjacent to socket 70A₁ and socket 70A₂, respectively, along the direction (i.e., the X direction) perpendicular to the direction of signal transmission. State differently, the four sockets 70 may be next to each other and arranged in a 2×2 square matrix along the Y direction and X direction. For example, sockets 70A₁, 70A₂, 70B₁, and 70B₂ are classified as Group G1. Similarly, sockets 70A₃, 70A₄, 70B₃, and 70B₄ form Group G2, while sockets 70C₁, 70C₂, 70D₁, and 70D₂ form Group G11, and so on.

With reference to FIGS. 5 and 6, the present embodiment describes how compensation circuits can address signal attenuation and delay caused by longer wiring paths, ensuring consistent and reliable test results. Since the rise and fall of test signals are symmetrical, the explanation focuses on the rise time, but the principles apply equally to fall times.

Test signals used for different types of DUT tests exhibit varying requirements. For example, clock testing involves only input signals, allowing for a relatively low test speed and longer rise times. In contrast, memory testing demands high-speed operation, requiring input and output signals with shorter rise and fall times for accurate data transfer during write and read operations. The rise time of test signals is significantly affected by the wiring length connecting connector 80 to sockets 70. For example, within the same socket row 75A, shorter wiring lengths, such as those in the first wiring system connecting sockets near the connector (e.g., 70A₁), result in minimal signal attenuation and shorter rise times. Conversely, longer wiring paths to distant sockets (e.g., 70A₂₀) experience greater attenuation, leading to extended rise times. For another example, within the same group G1, the sockets 70A₂, 70B₂ with longer wiring length also experience greater attenuation compared to the sockets 70A₁, 70B₁ with shorter wiring length.

With reference to FIGS. 3 to 7, a compensation circuit 90 (also referred to as the first compensation circuit 90) may be integrated to mitigate the adverse effects of longer wiring length between groups of sockets 70 along the same socket row. For example, for the socket row 75A, the compensation circuit 90 may be connected to the first wiring system 50a10 with extended lengths (e.g., the wiring 51a10), such as the wiring system 50a10 connecting the connector 80 to the farthest sockets (e.g., 70A₂₀). The compensation circuit 90 may employ an RC filter, including a parallel combination of a capacitor 91 and a resistor 92, to adjust the frequency characteristics of the transmitted signals. By functioning as a high-pass filter, the compensation circuit 90 may reduce the amplitude of low-frequency components while amplifying high-frequency components. This adjustment effectively shortens the rise time of the signal, allowing the compensated signal to meet the stringent timing requirements even when transmitted through longer wiring.

In some embodiments, the wiring 51a10 may be not limited to connect to the compensation circuit 90, but also connects, for example, to a terminating resistor for impedance matching between the input and output sides of the DUT 100. The compensation circuit 90 may also be connected to the first connection forms 50b1-50h10 or the second connection forms 60a-60p, not limited to the first wiring system 50a1-50a10.

FIG. 6 illustrates the frequency characteristics of the compensation circuit 90, where the horizontal axis represents frequency and the vertical axis represents gain. The compensation circuit 90 functions as a high-pass filter. When the test signal's frequency exceeds the high-side threshold frequency (fb), the compensation circuit 90 transmits the signal at the maximum gain Kb. Conversely, when the test signal's frequency is below the low-side threshold frequency (fa), the compensation circuit 90 transmits the signal at the minimum gain Ka. For frequencies between the low-side threshold frequency (fa) and the high-side threshold frequency (fb), the compensation circuit 90 outputs the signal with a gain that increases with frequency, ranging from Ka to Kb. In effect, the compensation circuit 90 reduces the amplitude of the low-frequency components of the signal relative to the high-frequency components.

The threshold frequencies (fa, fb) and the corresponding gains Ka and Kb are configured based on the required rise time of the test signal. For example, to achieve a shorter rise time, the threshold frequencies (fa, fb) may be set to lower values. In this way, the frequency characteristics of the test signal, adjusted by the compensation circuit 90, are tailored to meet the desired rise or fall time specifications for the test signal.

FIG. 7 illustrates the voltage characteristics of a signal compensated by the compensation circuit 90 compared to a signal not compensated by the compensation circuit 90. The vertical axis represents voltage, while the horizontal axis represents time. In this figure, Graph A shows the characteristics of signal A, which is not compensated by the compensation circuit 90, and Graph B shows the characteristics of signal B, which is compensated by the circuit. The rise time of a test signal is defined as the time it takes for the voltage to change from 20% to 80% of its maximum value during the rise, assuming the maximum voltage at the rise is 100%. In FIG. 7, A (100%) represents the maximum voltage at the rise of signal A, while A (80%) and A (20%) correspond to 80% and 20% of the maximum voltage at the rise of signal A, respectively. Similarly, B (100%) represents the maximum voltage at the rise of signal B, with B (80%) and B (20%) indicating 80% and 20% of the maximum voltage at the rise of signal B, respectively.

The rise time of signal A, which is not compensated by the circuit, is denoted as Ta, while the rise time of signal B, which is compensated by the circuit, is denoted as Tb (Tb<Ta). For the rise waveform of the test signal, the initial portion of the rise is predominantly influenced by the high-frequency components of the signal, while the latter portion of the rise is mainly affected by the low-frequency components. The compensation circuit 90 decreases the gain for low-frequency components while increasing the gain for high-frequency components. As shown in FIG. 7, for signal B, the voltage characteristics from the start of the rise until a certain point follow the same trend as signal A. However, the maximum voltage at the rise of signal B is lower than that of signal A. This means the compensation circuit 90 reduces the apparent rise time by suppressing the maximum voltage at the rise, without altering the slope of the voltage rise for the test signal. Consequently, the compensation circuit 90 effectively shortens the rise time of the test signal, even in wiring systems with extended lengths, allowing it to function efficiently with long wiring.

With reference to FIGS. 3, 4, and 8, in some embodiments, a compensation circuit 95 (also referred to as the second compensation circuit 95) may be integrated to mitigate the adverse effects of longer wiring length within the same group of sockets 70. For example, in the group G1, the sockets 70A₂, 70B₂ have longer wiring length compared to the sockets 70A₁, 70B₁. The compensation circuit 95 may be connected to the sockets 70A₂ (or 70B₂) with extended lengths (e.g., the wiring 51a2). The compensation circuit 95 may employ an RC filter, including a parallel combination of a capacitor 96 and a resistor 97, to adjust the frequency characteristics of the transmitted signals. By functioning as a high-pass filter, the compensation circuit 95 may reduce the amplitude of low-frequency components while amplifying high-frequency components. This adjustment effectively shortens the rise time of the signal, allowing the compensated signal to meet the stringent timing requirements even when transmitted through longer wiring. In some embodiments, the wiring 51a2 may be part of the first wiring system 50a1.

The compensation circuit 95 may also be connected to the first connection forms 50a2 to 50h10 not limited to the first wiring system 50a1.

The compensation circuit's design reduces low-frequency amplitude relative to high-frequency amplitude, enabling the burn-in apparatus 1 to maintain high test accuracy. Wiring systems with varying lengths are optimized by connecting the compensation circuit to the longer wiring paths. This ensures uniform signal performance across all connections. By compensating for frequency characteristics in alignment with the required signal dynamics, the burn-in apparatus 1 may achieve consistent rise and fall times, improving overall test reliability and scalability.

By organizing the plurality of sockets 70 into groups based on the signal transmission path (i.e., arranged in a 2×2 square matrix along the Y and X directions), signal delay occurs only once within each group. For instance, in group G1, the signal delay is limited to occurring either between sockets 70A₁ and 70A₂ or between sockets 70B₁ and 70B₂. This signal delay can be compensated for using the compensation circuit 95 or by systematically adjusting the offset for sockets 70A₂ and 70B₂.

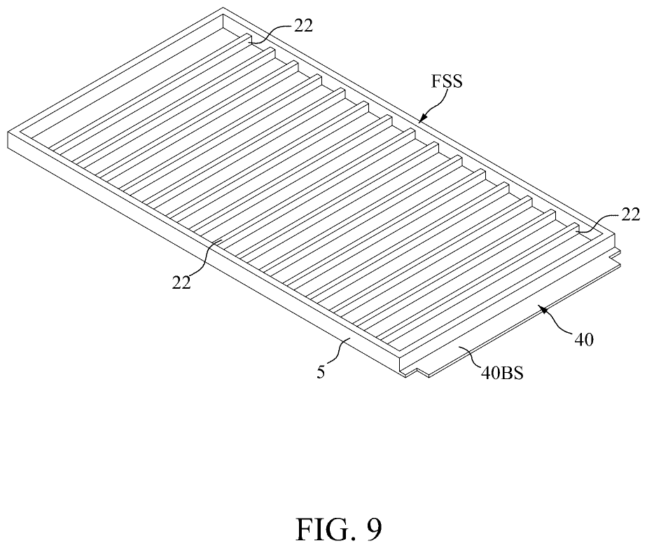

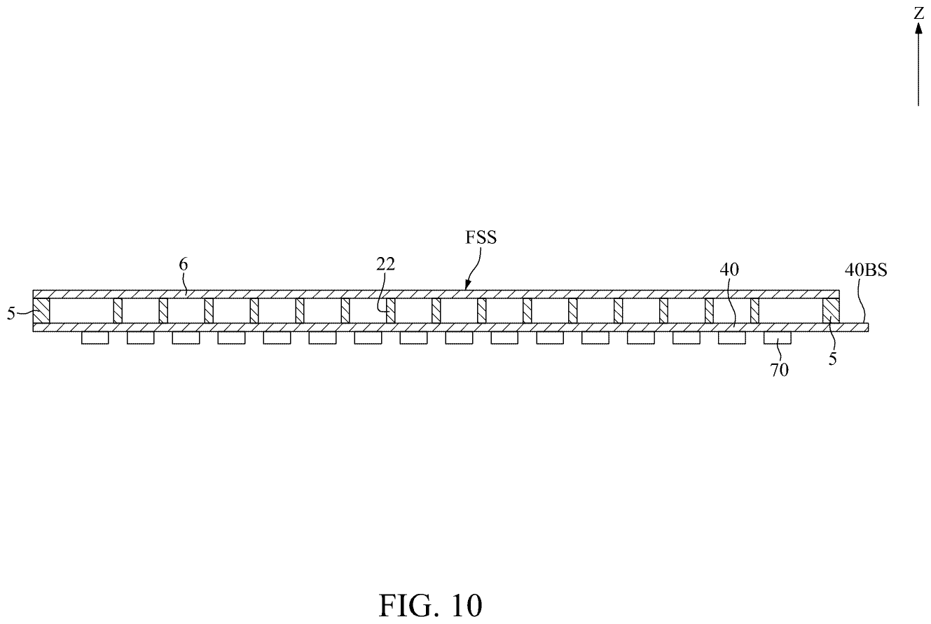

FIG. 9 is a perspective view of the burn-in board 20 with a flexure prevention structure FSS in accordance with one embodiment of the present disclosure. FIG. 10 is a vertical sectional view of the burn-in board 20 with the flexure prevention structure FSS in accordance with one embodiment of the present disclosure.

With reference to FIGS. 9 and 10, the burn-in board 20 may further include a flexure prevention structure FSS. When placing a DUT 100 onto each socket 70 of the burn-in board 20 using a device installation and removal device, significant mechanical pressure is exerted on the DUT 100. This pressure, along with any resulting vibrations, is transferred to the board-substrate 40 through the socket 70. To prevent the board-substrate 40 from bending or flexing under such mechanical stress or vibrations, the flexure prevention structure FSS may be implemented on the back surface 40BS of the board-substrate 40. This structure ensures the burn-in board 20 maintains its integrity and stability during operation.

With reference to FIGS. 9 and 10, in some embodiments, the flexure prevention structure FSS may include a large number of square pillar-shaped supporting rods 22. The supporting rods 22 may be attached to the back surface 40BS of the board-substrate 40 to provide structural support. In some embodiments, the supporting rods 22 may be firmly fixed to the back surface 40BS of the board-substrate 40 by screwing or using an adhesive to secure them to prevent displacement.

With reference to FIGS. 9 and 10, in some embodiments, the flexure prevention structure FSS may include a reinforcing frame 5. The reinforcing frame 5, constructed from rectangular bars to form a rectangular frame body, may be fixed near the edges of the back surface 40BS of the board-substrate 40. The reinforcing frame 5 may provide additional structural support, ensuring rigidity and stability, particularly in areas prone to stress or deformation. By being positioned close to the edges, the reinforcing frame 5 may effectively minimize flexing or bending of the structure under applied forces.

With reference to FIGS. 9 and 10, in some embodiments, the flexure prevention structure FSS may include a protective cover 6. The protective cover 6 may be designed as a rectangular flat plate and further added to enhance the structural integrity and safeguard the supporting rods 22 and the reinforcing frame 5. The protective cover 6 may be affixed securely to the reinforcing frame 5, ensuring a stable and protective enclosure. By attaching the protective cover 6 to the reinforcing frame 5, the flexure prevention structure FSS may achieve both mechanical protection and a clean, streamlined appearance, effectively shielding the underlying supporting rods 22 from external forces or environmental factors.

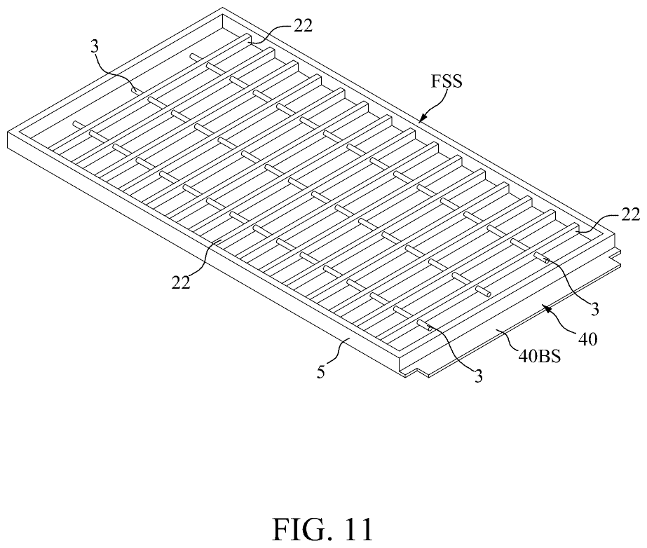

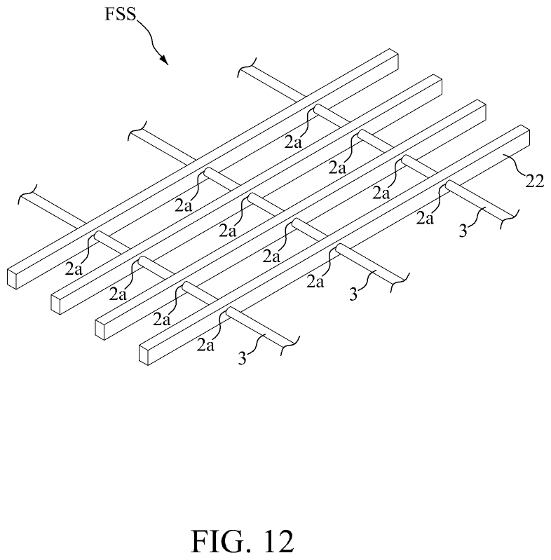

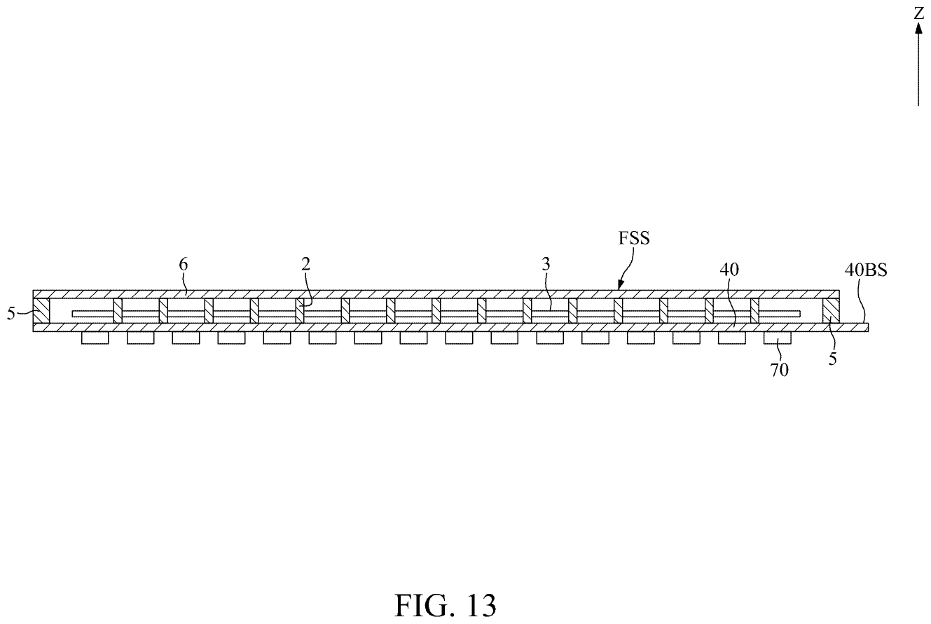

FIG. 11 is a perspective view of the burn-in board 20 with a flexure prevention structure FSS in accordance with another embodiment of the present disclosure. FIG. 12 is a perspective view showing a portion of the flexure prevention structure FSS provided on the burn-in board 20 in accordance with another embodiment of the present disclosure. FIG. 13 is a vertical sectional view of the burn-in board with the flexure prevention structure FSS in accordance with another embodiment of the present disclosure.

With reference to FIGS. 11 to 13, in some embodiments, the flexure prevention structure FSS may be composed of supporting members, including a plurality of supporting rods 22, connecting members, including a plurality of connecting rods 3, a reinforcing frame 5, and a protective cover 6.

The reinforcing frame 5, constructed from rectangular bars to form a rectangular frame body, may be fixed near the edges of the back surface 40BS of the board-substrate 40. The reinforcing frame 5 may provide additional structural support, ensuring rigidity and stability, particularly in areas prone to stress or deformation. By being positioned close to the edges, the reinforcing frame 5 may effectively minimize flexing or bending of the structure under applied forces.

Each supporting rod 22 may be a square rod with a height approximately equal to that of the reinforcing frame 5. The longitudinal length of each supporting rod 22 may be designed to fit within the width of the reinforcing frame 5. On the side surface of each supporting rod 22, circular through holes 2a may be formed. The through holes 2a may have a shape and size closely matching the cross-sectional profile of the circular rod-like connecting rods 3, ensuring a snug fit.

The connecting rods 3 may be designed to penetrate through the through holes 2a in the supporting rods 22. Each connecting rod 3 may have a longitudinal length that fits within the length of the reinforcing frame 5. Before installation, the connecting rods 3 may be inserted into the through holes 22 of the supporting rods, effectively threading the supporting rods 22 onto the connecting rods 3. This connection may integrate all supporting rods 22 into a unified structure, enhancing the rigidity of the flexure prevention structure FSS.

Because the through holes 2a in the supporting rods 22 match the shape and size of the cross-section of the connecting rods 3, the connecting rods 3 cannot easily slide or slip out once inserted. This secure connection ensures that the supporting rods 22 remain firmly in place relative to the connecting rods 3, providing high overall rigidity. As a result, if an external force is applied to one of the supporting rods 22, the force is distributed across the entire flexure prevention structure FSS, preventing displacement or collapse of any individual supporting rod 22.

Once assembled, the entire flexure prevention structure FSS, consisting of the interconnected supporting rods 22 and connecting rods 3, may be placed on the back surface 40BS of the board-substrate 40. The protective cover 6, in the form of a rectangular flat plate, may be then placed over the flexure prevention structure FSS. This cover is attached to the reinforcing frame 5, securing the entire assembly in place.

The supporting rods 22, having the same height as the reinforcing frame 5, are situated between the board-substrate 40 and the protective cover 6. They provide continuous support by being in direct contact with both the board-substrate 40 and the protective cover 6, effectively preventing flexure of the board-substrate 40 under applied forces. This integrated design ensures a stable and durable structure capable of withstanding mechanical stress and vibrations.

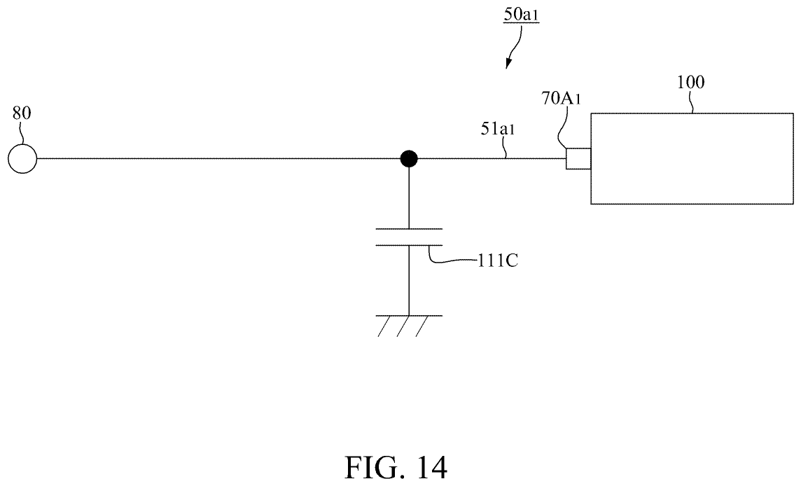

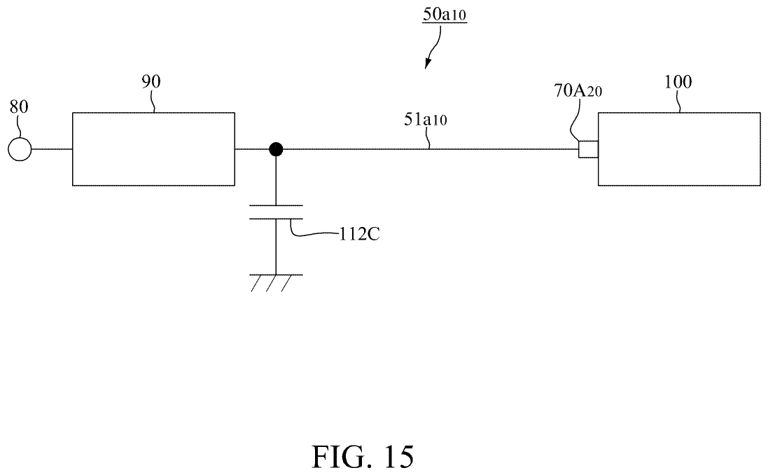

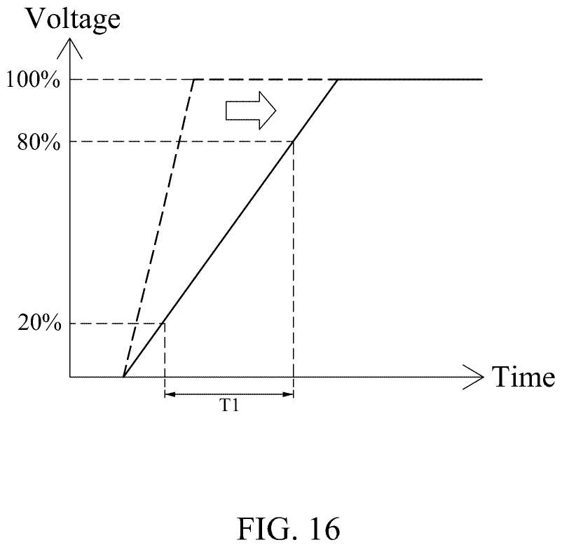

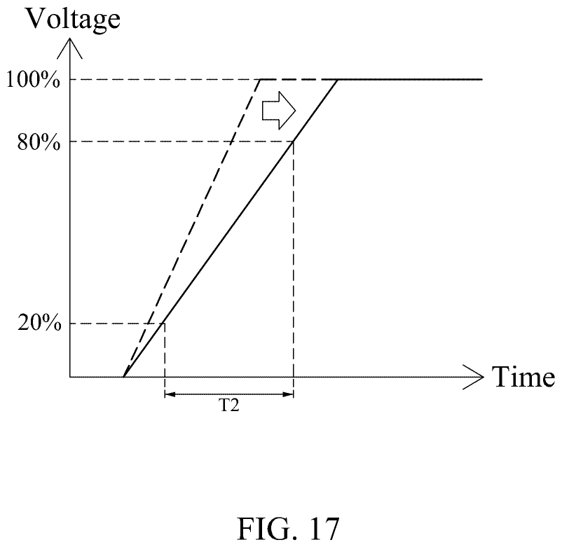

FIGS. 14 and 15 illustrate wiring circuits of a burn-in board 20 in accordance with one embodiment of the present disclosure. FIGS. 16 and 17 are graphs illustrating the rise time of signals transmitting through the wiring circuits in FIGS. 14 and 15.

In some embodiments, the burn-in board 20 may include external capacitors connected to the first wiring systems 50a1 to 50h10 and/or the second wiring systems 60a to 60p. The embodiments differ from the embodiments illustrated in FIGS. 1 to 8 primarily in the inclusion of these external capacitors, while the other configurations remain the same. Only the differences are described here, with components identical to those in the embodiments illustrated in FIGS. 1 to 8 retaining the same reference symbols and being omitted from further explanation.

With reference to FIGS. 14 and 15, the first wiring system 50a1 may include a segment of wiring 51a1 that connects the branch point of the wiring system to the connector 80. A first capacitor 111C may be connected to wiring 51a1. Similarly, the first wiring system 50a10 may include a segment of wiring 51a10 that connects the branch point of the system to the connector 80. A second capacitor 112C may be connected to wiring 51a10. The capacitance of the first capacitor 111C may be greater than that of the second capacitor 112C. The connection point of the second capacitor 112C is not limited to downstream of the compensation circuit 90, as shown in FIG. 15, but can also be upstream.

Each socket, such as 70A₁, is equipped with multiple densely arranged contact pins that correspond to the terminals of the DUT 100. This dense arrangement is consistent across other sockets like 70A₂ to 70P₂₀, and the short distances between adjacent pins and wires on the board-substrate 40 can lead to crosstalk, especially with high-frequency signals. Crosstalk becomes more pronounced when the rise and/or fall time of the test signal is short, as such signals contain more high-frequency components. While reducing high-frequency components can suppress crosstalk, it also increases the rise and/or fall time of the test signal. This creates a trade-off between minimizing crosstalk and maintaining signal timing performance. Additionally, as shown in the embodiments illustrated in FIGS. 1 to 13, the rise and fall times of the test signal may be influenced by the wiring length.

With reference to FIGS. 14 to 17, the capacitors 111C and 112C may be connected to wiring 51a1 and 51a10, respectively, to balance the trade-off between crosstalk suppression and the required rise and/or fall time of the test signal. For wiring 51a1, which has a shorter length and experiences minimal signal attenuation, the rise time is naturally shorter, as illustrated by the dotted line graph in FIG. 16. To address this, the first capacitor 111C, with a larger capacitance, may be connected to the wiring 51a1. This increases the rise time (T1), as shown by the solid line graph in FIG. 16, effectively suppressing high-frequency components and mitigating crosstalk.

With reference to FIGS. 14 to 17, for the wiring 51a10, which has a longer length and greater signal attenuation, the rise time is naturally longer, as shown by the dotted line graph in FIG. 17. Here, the second capacitor 112C, with a smaller capacitance, may be connected to 51a10. This results in a moderate increase in rise time (T2), as shown by the solid line graph in FIG. 17. Although the adjustment range for the rise time with the second capacitor 112C is narrower than that of the first capacitor 111C, the suppression of high-frequency components in the test signal reduces crosstalk effectively.

Thus, the burn-in board 20 and the burn-in apparatus 1 in this embodiment utilize the external capacitors 111C, 112C, connected to the first wiring systems 50a1 and 50a10. These wiring systems connect multiple sockets, such as 70A₁ and 70A₂, to the connector 80, with wiring lengths varying across the system. The first capacitor 111C is connected to the shorter wiring segment 51a1, while the second capacitor 112C is connected to the longer wiring segment 51a10. The arrangement suppresses crosstalk and maintains an acceptable rise and/or fall times for the test signals.

External capacitors may also be connected to other wiring systems within the burn-in board 20, such as 50a2 to 50a9 and 50b1 to 50h10. In such cases, the capacitance of the capacitors can be scaled based on the wiring length, with shorter wires requiring capacitors of larger capacitance.

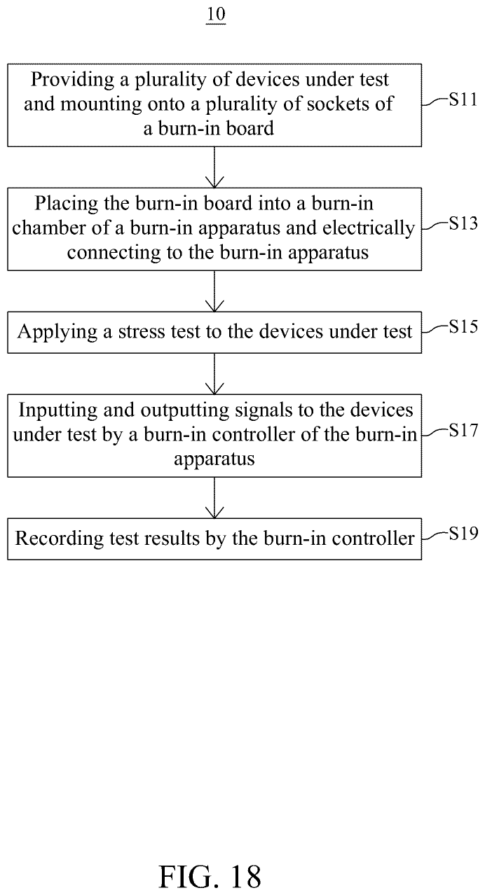

FIG. 18 illustrates, in a flowchart diagram form, a burn-in process 10 in accordance with one embodiment of the present disclosure.

At Step S11, a plurality of devices under test 100 may be provided and mounted onto a plurality of sockets 70 of a burn-in board 20.

At Step S13, the burn-in board 20 may be placed into a burn-in chamber 11 of a burn-in apparatus 1 and electrically connected to the burn-in apparatus 1. The burn-in chamber 11 may be designed to accommodate the burn-in board 20 and apply thermal stress to the DUTs 100. The electrical connections between the burn-in board 20 and the burn-in chamber 11 may be established through a connector 80 of the burn-in board 20 and a connector 115 of burn-in apparatus 1.

At Step S15, a stress test may be applied to the DUTs 100. The temperature of the stress test may be between about −25° C. to about +125° C. The burn-in chamber 11 may utilize evaporator 116, heater 117, and fan 118 to regulate the temperature within the burn-in chamber 11, ensuring consistent thermal conditions for the stress test.

At Step S17, signals may be input and output to the DUTs 100 by a burn-in controller 13 of the burn-in apparatus 1. The signals may be transmitted to the DUTs 100 through a wiring system 50 of the burn-in board 20. In some embodiments, the signals, which may include test signals for evaluating the DUT's functionality, can impact the quality of the burn-in process depending on their rise and fall times. During the burn-in process, the burn-in controller 13 may monitor the DUT's response to the input signals. Any DUTs 100 exhibiting abnormal responses may be identified by the burn-in controller as defective products.

At Step S19, test results may be recorded by the burn-in controller 13.

One aspect of the present disclosure provides a burn-in board including a board-substrate including a front surface and a back surface; a plurality of sockets mounted on the front surface of the board-substrate; and a wiring system positioned in the board-substrate and electrically connected to the sockets. The plurality of sockets are configured into groups by the wiring system. The groups respectively include four sockets arranged in a 2×2 square matrix.

Another aspect of the present disclosure provides a burn-in apparatus including a burn-in chamber; a burn-in board accommodated in the burn-in chamber; a test power supply electrically connected to the burn-in board; and a burn-in controller electrically connected to the burn-in board. The burn-in board includes a board-substrate including a front surface and a back surface, a plurality of sockets mounted on the front surface of the board-substrate, and a wiring system positioned in the board-substrate and electrically connected to the sockets, wherein the plurality of sockets are configured into groups by the wiring system, and the groups respectively includes four sockets arranged in a 2×2 square matrix.

Another aspect of the present disclosure provides a burn-in process including providing a plurality of devices under test; providing a burn-in board including a board-substrate including a front surface and a back surface, a plurality of sockets mounted on the front surface of the board-substrate, and a wiring system positioned in the board-substrate, electrically connected to the sockets, and configured the plurality of sockets into groups, wherein the groups respectively includes four sockets arranged in a 2×2 square matrix; installing the plurality of devices under test on the plurality of sockets; placing the burn-in board into a burn-in chamber of a burn-in apparatus and electrically connecting the burn-in board and the burn-in apparatus; performing a stress test to the plurality of devices under test; providing to and receiving from signals from the plurality of devices under test by a burn-in controller of the burn-in apparatus through the wiring system of the burn-in board; and recording test results by the burn-in controller of the burn-in apparatus.

Due to the design of the burn-in board of the present disclosure, the number of sockets 70 can be increased (e.g., up to a total of 320 sockets) without compromising signal synchronization either among sockets 70 in different groups or within the same group. This is achieved through the tailored design of the signal transmission path according to the wiring system 50.

Although the present disclosure and its advantages have been described in detail, it should be understood that various changes, substitutions and alterations can be made herein without departing from the spirit and scope of the disclosure as defined by the appended claims. For example, many of the processes discussed above can be implemented in different methodologies and replaced by other processes, or a combination thereof.

Moreover, the scope of the present application is not intended to be limited to the particular embodiments of the process, machine, manufacture, composition of matter, means, methods and steps described in the specification. As one of ordinary skill in the art will readily be appreciated from the disclosure of the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, and steps.

What is claimed is:

1. A burn-in board, comprising:
a board-substrate comprising a front surface and a back surface;
a plurality of sockets mounted on the front surface of the board-substrate; and
a wiring system positioned in the board-substrate and electrically connected to the sockets;
wherein the plurality of sockets are configured into groups by the wiring system;
wherein the groups respectively comprise four sockets arranged in a 2×2 square matrix.

2. The burn-in board of claim 1, further comprises a connector attached to the board-substrate and electrically connected to the wiring system.

3. The burn-in board of claim 2, wherein the board-substrate has approximately a rectangular shape.

4. The burn-in board of claim 3, wherein a number of the plurality of sockets is 320.

5. The burn-in board of claim 3, wherein a number of the groups is 80.

6. The burn-in board of claim 3, wherein the wiring system comprises a plurality of wirings of different lengths connected to the connector.

7. The burn-in board of claim 6, further comprising a first compensation circuit electrically connected to a wiring with the longest wiring length among the plurality of wirings.

8. The burn-in board of claim 7, wherein the first compensation circuit compensates a frequency characteristic of a signal transmitted through the wiring system.

9. The burn-in board of claim 7, wherein the compensation circuit comprises a parallel combination of a capacitor and a resistor.

10. The burn-in board of claim 7, further comprising an external capacitor electrically connected to the wiring system.

11. The burn-in board of claim 7, further comprising a first capacitor electrically connected to a wiring with the shortest wiring length among the plurality of wirings, and a second capacitor electrically connected to a wiring with the longest wiring length among the plurality of wirings, wherein a capacitance of the first capacitor is greater than a capacitance of the second capacitor.

12. The burn-in board of claim 7, further comprising a flexure prevention structure positioned on the back surface of the board-substrate.
